(19) United States
(12) Patent Application Publication
(10) Pub. No.: US 2024/0210625 A1
(43) Pub. Date: Jun. 27, 2024

(54) Low Temperature Fabrication of Silicon Nitride Photonic Devices

(71) Applicant: The Regents of the University of California, Oakland, CA (US)

(72) Inventors: Debapam Bose, Oakland, CA (US); Jiawei Wang, Goleta, CA (US); Daniel J. Blumenthal, Santa Barbara, CA (US)

(73) Assignee: The Regents of the University of California, Oakland, CA (US)

(21) Appl. No.: 18/395,038

(22) Filed: Dec. 22, 2023

Related U.S. Application Data
(60) Provisional application No. 63/476,887, filed on Dec. 22, 2022.

(51) Int. Cl. G02B 6/136

(52) U.S. Cl. CPC G02B 6/136; C23C 16/401

(57) ABSTRACT

Disclosed herein is methods for fabricating ultra-low loss waveguides. One particular method may include: preparing a substrate including a lower cladding layer in a deposition chamber; flowing precursors including deuterated silane and nitrogen onto the lower cladding layer in the deposition chamber; subjecting the precursors to an inductively coupled plasma-plasma enhanced chemical vapor deposition (ICP-PECVD) process which disassociates the deuterated silane and nitrogen and deposits waveguide material of silicon nitride or silicon oxynitride onto the lower cladding layer; patterning the waveguide material into a patterned waveguide material; and depositing a top cladding layer on the patterned waveguide material, wherein the ICP-PECVD process occurs at a temperature less than or equal to 250° C. Advantageously, the ICP-PECVD process allows for deposition of low hydrogenated deposition of material layers which may allow for low temperature fabrication of ultra-low loss waveguides.

### CROSS-REFERENCE TO RELATED APPLICATIONS

This application claims the benefit of and priority under 35 U.S.C. § 119(e) to U.S. Provisional Patent Application Ser. No. 63/476,887 filed on Dec. 22, 2022, which is incorporated herein by reference in its entirety for all purposes.

### STATEMENT OF FEDERALLY SPONSORED RESEARCH

This invention was made with government support under HR0011-22-2-0008 awarded by the Defense Advanced Research Projects Agency, and W911NF-22-2-0056 awarded by the Army Research Laboratory—Army Research Office. The government has certain rights in the invention.

### FIELD OF THE INVENTION

The present invention generally relates to low temperature fabrication of photonic devices.

### BACKGROUND

Photonic integrated circuits can provide benefit to a wide range of applications by reducing their size, weight, power consumption, and cost as well as improving reliability, scalability, performance, and manufacturability, similar to the benefits microelectronics has brought. Such applications include optical and fiber communications, data centers interconnects and cloud communications and computing, optical gyroscopes and laser-based position and navigation, Light Detection and Ranging (LIDAR), atomic and optical clocks and timekeeping, quantum sensors and computing, quantum communications, space-based applications, and fundamental physics experiments.

Photonic integrated circuits, provide the ability to co-locate, at the chip-scale, a wide array of interconnected components and functions required by these applications, including lasers, modulators, detectors, and other optical components, sub-systems, and systems, that normally occupy tables, racks and equipment boxes. Components and integrated photonic circuits may be able to support design and operation over a broad range of performance specifications including operating at optical frequencies from the ultra-violet, through the visible, and into the infrared. Additionally, many applications include that the waveguides, the optical wires that route photons, and other components on these circuits, operate with very low optical loss. In order to reduce cost and provide manufacturable solutions, these ultra-low loss, wavelength independent, integrated circuits may be fabricated using processes that are compatible with standard wafer-scale CMOS foundry processes.

In addition to low optical loss, some applications include tuning and modulation of lasers, optical components, and optical signals. Examples include tuning of laser wavelengths and optical filters, modulation of the phase and/or amplitude of an optical signal, and modulation of an optical signal to perform control functions such as locking a laser to an optical reference cavity, atom, or ion or communications channel control signals. It may be advantageous that the mechanisms used to accomplish tuning and modulation be compatible with the optical waveguides and photonic waveguide, including transparency to the optical wavelength and the ability to modulate without affecting the low optical losses and other desirable attributes of the optical waveguide and photonic integrated circuit. Low temperature fabrication of optical waveguides may lead to higher applicability of these waveguides in a greater number of photonic structures.

### SUMMARY OF THE INVENTION

In some aspects, the techniques described herein relate to a method for fabricating an ultra-low loss waveguide including: preparing a substrate including a lower cladding layer in a deposition chamber; flowing precursors including deuterated silane and nitrogen onto the lower cladding layer in the deposition chamber; subjecting the precursors to an inductively coupled plasma-plasma enhanced chemical vapor deposition (ICP-PECVD) process which disassociates the deuterated silane and nitrogen and deposits waveguide material of silicon nitride or silicon oxynitride onto the lower cladding layer; patterning the waveguide material into a patterned waveguide material; and depositing an upper cladding layer on the patterned waveguide material, wherein the ICP-PECVD process occurs at a temperature less than or equal to 250° C.

In some aspects, the techniques described herein relate to a method, wherein the substrate includes a substrate material selected from the group consisting of: silicon, quartz, a III-V semiconductor, and a polymer.

In some aspects, the techniques described herein relate to a method, wherein the upper cladding layer includes silicon oxide.

In some aspects, the techniques described herein relate to a method, wherein depositing the upper cladding layer includes flowing vapor precursors of silane, oxygen, and argon onto the lower patterned waveguide material and subjecting the vapor precursors to an ICP-PECVD process which disassociates the silane and oxygen and deposits waveguide material of silicon oxide onto the patterned waveguide material.

In some aspects, the techniques described herein relate to a method, wherein the lower cladding layer includes silicon oxide.

In some aspects, the techniques described herein relate to a method, further including depositing the lower cladding layer.

In some aspects, the techniques described herein relate to a method, wherein depositing the lower cladding layer includes flowing vapor precursors of deuterated silane, oxygen onto the lower patterned waveguide material and subjecting the vapor precursors to an ICP-PECVD process which disassociates the silane and oxygen and deposits waveguide material of silicon oxide onto the substrate.

In some aspects, the techniques described herein relate to a method, wherein the waveguide material has a thickness of less than 200 nm.

In some aspects, the techniques described herein relate to a method, wherein the waveguide material has a thickness between 40 nm and 175 nm.

In some aspects, the techniques described herein relate to a method, wherein patterning the waveguide material includes: coating the waveguide material with a photoresist; exposing the photoresist through a mask to transfer a pattern onto the photoresist; etching the waveguide material through the photoresist; and removing the photoresist.

In some aspects, the techniques described herein relate to a method, wherein exposing the photoresist through a mask is performed with a stepper.

In some aspects, the techniques described herein relate to a method, wherein etching the waveguide material is performed with a reactive ion etch process.

In some aspects, the techniques described herein relate to a method, wherein the reactive ion etch process is an inductively coupled plasma-reactive ion etch (ICP-RIE) process, wherein the ICP-RIE process is performed at a temperature of 250° C. or less.

In some aspects, the techniques described herein relate to a method, wherein the ICP-RIE process is performed at a temperature of 50° C. or less.

In some aspects, the techniques described herein relate to a method, wherein the waveguide material has a thickness of greater than or equal to 200 nm.

In some aspects, the techniques described herein relate to a method, wherein the waveguide material has a thickness between 200 nm and 800 nm.

In some aspects, the techniques described herein relate to a method, wherein patterning the waveguide material includes: depositing a hard mask layer on the waveguide material; coating the hard mask layer with a photoresist; exposing the photoresist through a mask to transfer a pattern onto the photoresist; etching the hard mask layer through the photoresist; removing the photoresist; etching the waveguide material through the hard mask layer; and removing the hard mask layer.

In some aspects, the techniques described herein relate to a method, wherein exposing the photoresist through a mask is performed with a stepper.

In some aspects, the techniques described herein relate to a method, wherein etching the waveguide material is performed with a reactive ion etch process.

In some aspects, the techniques described herein relate to a method, wherein the reactive ion etch process is an inductively coupled plasma-reactive ion etch (ICP-RIE) process, wherein the ICP-RIE process is performed at a temperature of 250° C. or less.

In some aspects, the techniques described herein relate to a method, wherein the ICP-RIE process is performed at a temperature of 50° C. or less.

In some aspects, the techniques described herein relate to a method, wherein depositing the hard mask layer includes sputtering a hard mask material onto the waveguide material.

In some aspects, the techniques described herein relate to a method, wherein the hard mask layer includes Ruthenium.

In some aspects, the techniques described herein relate to a method, wherein etching the hard mask layer is performed with a reactive ion etch process.

In some aspects, the techniques described herein relate to a method, wherein the reactive ion etch process is an inductively coupled plasma-reactive ion etch (ICP-RIE) process, wherein the ICP-RIE process is performed at a temperature of 250° C. or less.

In some aspects, the techniques described herein relate to a method, wherein the ICP-RIE process is performed at a temperature of 50° C. or less.

In some aspects, the techniques described herein relate to a method, wherein the precursors further include a noble gas.

In some aspects, the techniques described herein relate to a method, wherein the noble gas includes argon.

In some aspects, the techniques described herein relate to a method, wherein the deuterated silane includes deuterium.

In some aspects, the techniques described herein relate to a method, wherein the nitrogen includes molecular nitrogen gas.

In some aspects, the techniques described herein relate to a method, wherein the oxygen includes molecular oxygen gas.

In some aspects, the techniques described herein relate to a method, further including: flowing precursors including deuterated silane and nitrogen onto the upper cladding layer in the deposition chamber; subjecting the precursors to an ICP-PECVD process which disassociates the deuterated silane and nitrogen and deposits waveguide material of silicon nitride or silicon oxynitride onto the upper cladding layer; and patterning the waveguide material into a second patterned waveguide material.

In some aspects, the techniques described herein relate to a method, further including depositing a second upper cladding layer on top of the second patterned waveguide material.

In some aspects, the techniques described herein relate to a heterogeneously integrated ultra-low loss optical waveguide including: a substrate including electronic or photonic circuits in a material system that is not compatible with high temperature processing above 250° C.; a lower cladding layer positioned on top of the lower substrate fabricated with a maximum temperature of 250° C.; a first waveguide core layer positioned on top of the lower cladding layer fabricated with a maximum temperature of 250° C.; and a first upper cladding layer positioned on top of the waveguide core layer fabricated with a maximum temperature of 250° C.

In some aspects, the techniques described herein relate to an optical waveguide, wherein the substrate is selected from the group consisting of: silicon photonics, electronic circuits, printed circuit boards, organic circuits, lithium niobate, BTO, quartz, sapphire, and silicon carbide.

In some aspects, the techniques described herein relate to an optical waveguide, wherein the first waveguide core layer is a nitride layer including a thickness from 20 nm to 1 micron with maximum processing temperature of 250° C.

In some aspects, the techniques described herein relate to an optical waveguide, wherein the thickness of the first waveguide core is between 5 nm and 20 nm.

In some aspects, the techniques described herein relate to an optical waveguide, wherein the thickness of the first waveguide is between 1 micron and 2 microns.

In some aspects, the techniques described herein relate to an optical waveguide, further including a second waveguide core layer positioned on the first upper cladding layer and a second upper cladding layer positioned on the second waveguide core, wherein the second waveguide core and the second upper cladding layer are fabricated with a maximum processing temperature of 250° C.

In some aspects, the techniques described herein relate to an optical waveguide, wherein the second waveguide core layer has a different thickness than the first waveguide core layer.

In some aspects, the techniques described herein relate to an optical waveguide, wherein the first waveguide core layer and the second waveguide core layer support ultra-low loss with dilute optical modes using thin cores and thick cores for nonlinear optical effects and dispersion engineering.

In some aspects, the techniques described herein relate to an optical waveguide, wherein the first waveguide core layer and the second waveguide core layer support wavelengths from 200 nm to 2350 nm and include silicon nitride, aluminum oxide, tantalum pentoxide, or aluminum nitride.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The description will be more fully understood with reference to the following figures, which are presented as exemplary embodiments of the invention and should not be construed as a complete recitation of the scope of the invention, wherein:

FIG. 1 illustrates examples of different applications of different devices which may be produced.

FIG. 2 is various stages of fabrication of a photonic device in accordance with an embodiment of the invention.

FIG. 3A is a top down photograph of a patterned silicon nitride layer 206a on the silicon dioxide cladding layer 208 manufactured with the process described in connection with FIG. 2.

FIG. 3B is a schematic perspective view of an example photonic device manufactured with the process described in connection with FIG. 2.

FIG. 3C is a schematic perspective view of an example photonic device manufactured with the process described in connection with FIG. 2.

FIG. 3D is a top down photograph of an example patterned silicon nitride 206a on the silicon dioxide cladding layer 208 manufactured with the process described in connection with FIG. 2.

FIG. 4 illustrates a SiN X-ray photoelectron spectroscopy (XPS) measurement.

FIG. 5 is a top-down Scanning Electron Microscopy (SEM) image of a fabricated ring resonator near the coupling gap before upper cladding deposition.

FIG. 6 is a top-down SEM image of a fabricated ring resonator.

FIG. 7A is various plots illustrating TM mode loss and intrinsic Q variation vs wavelength for 3 different devices.

FIG. 7B are various plots illustrating Transverse Magnetic (TM) mode resonance Q measurement.

FIG. 8A is various plots of loss and intrinsic Q variation vs wavelength for the Transverse Electric (TE) and Transverse Magnetic (TM) modes.

FIG. 8B is various plots of TE mode resonance Q measurement at 581 nm.

FIG. 8C is various plots of TM mode resonance Q measurement at 1560 nm.

FIG. 9 illustrates example nonlinear application results of thick 800 nm waveguides and resonators.

Turning back to the figures, FIG. 10 illustrates a method 1000 for fabricating an ultra-low loss waveguide.

FIG. 11 is a flow chart of an example method of manufacturing a thin silicon nitride waveguide.

FIG. 12 illustrates an example method of manufacturing a thick silicon nitride waveguide.

FIG. 13 is a cross-sectional schematic of an example ICP-PECVD apparatus 1300.

FIG. 14 is a flow chart of an example method of manufacturing a thin silicon nitride waveguide.

### DETAILED DESCRIPTION

Integrated photonics with ultra-low loss waveguides are important for applications including (but not limited to) quantum computing and sensing, precision metrology atomic clocks, biosensing, and fiber optic communications. Integrated photonics with ultra-low loss waveguides can operate across the visible to infrared wavelength spectrum, and also bring bulk optical component performance to the chip-scale without compromising performance. Conventional methods of fabricating ultra-low loss waveguides, such as the silicon nitride platforms, include high temperature processes such as annealing to drive out impurities to reduce the losses. Such losses can be due to hydrogen introduced during the oxide or nitride deposition process involved in forming the waveguides and photonic circuits. High temperatures may drive out the impurities. These high temperatures for annealing can exceed 500° C. and can be up to 1200° C. or higher. For example, LPCVD-grown silicon nitride may include a nitride growth at 800° C. There may be a subsequent post oxide cladding anneal which may occur at about 1150° C. However, many photonic chip manufacturing processes cannot survive the high temperatures. For examples, ultra-low loss waveguides can be grown on top of silicon CMOS chips, but a pre-fabricated CMOS chip cannot survive temperatures above 250° C. This temperature is significantly lower than the temperatures required for LPCVD-grown silicon nitride as discussed above. In addition, some examples of waveguides may be deposited on quartz. Quartz may be preferable to grow ultra-low loss waveguides on top of for applications such as optical reference cavities due to the optical and thermal properties. Quartz cannot sustain large temperature differentials without cracking and thus the high temperatures for LPCVD-grown silicon nitride may not be compatible with waveguides grown on top of Quartz.

Further, the waveguide material may be made of a material not compatible with high temperature processing. The waveguide material may be tantalum pentoxide (Tantala). Tantala may crystalize above 580° C. Thus, manufacturing processes for low loss waveguides that are compatible with low temperatures may be advantageous. Other designs may use a substrate or other waveguide material as the base, which has limitations to the processing temperature of adding a silicon nitride, tantala, or other layer on top, for example a processed silicon photonics wafer or device, a quartz wafer or a sapphire wafer.

The low loss waveguide may be incorporated in various material systems and integration platforms, capabilities such as optical gain, high speed modulation, optical nonlinearities, and photodetection. These capabilities can be combined with the ultra-low loss integration through heterogeneous integration with materials that cannot withstand high annealing temperatures normally required to achieve low loss, such as silicon photonic circuits, GaAs and InP semiconductor circuits, and nonlinear materials such as lithium niobate and tantalum pentoxide (tantala) as well as materials for thermal engineering such as quartz substrates, and organic electronic and photonic circuits. In the past integration of these materials with ultra low loss photonics, such as silicon nitride photonics, has been inhibited by their incompatibility with the high temperature nitride growth and high-temperature post-oxide cladding annealing process that is used to achieve low losses and added process complexity that can occur with silicon nitride waveguides such as stress mitigation and costly chemical mechanical polishing (CMP). For heterogeneous integration a maximum fabrication temperature may include 250 degrees C., 200 degrees C., 100 degrees C., or 50 degrees C. Thus, the disclosed invention allows for the functionality of heterogeneous and monolithic integration to the silicon nitride platform without annealing, while maintaining the ultra-low loss advantage and provide the same wafer-scale processing steps for both thin and thick silicon nitride waveguides.

Combinations of different types of ultra-low loss waveguides, including thin waveguides and thick waveguides, and the ability to heterogeneously integrate in 3D structures a wide range of ultra low loss waveguide thicknesses as well as with other material systems may be advantageous. Such integration of a wide range of waveguide thicknesses provide benefits to design in the properties of waveguides including mode confinement, dispersion, and optical intensity. Therefore, it may be advantageous for the integration process to integrate a wide range of low loss waveguide designs at low temperatures that can also accommodate integration with a wide range of other materials and integration platforms.

Disclosed herein is low loss integrated waveguides and high Q factor ring resonators, and other low loss components fabricated completely with low temperature processed silicon nitride photonics with maximum processing temperature off 250° C. for all steps. Maximum processing temperatures of 150° C., 100° C., and 50° C. may also be provided to provide compatibility with other materials such as organics. Patterned silicon nitride layers may be used for both thin and thick waveguides to provide design flexibility such as optical mode confinement, dispersion, and loss in order to realize desirable characteristics such as loss and nonlinearities. A diverse range of geometries of waveguides and ring resonators may be fabricated for linear and nonlinear applications with 10× dynamic range in nitride thicknesses and over 10× dynamic range in nitride thickness and without any process modification, or the use of stress mitigation, or chemical mechanical polishing (CMP). This low temperature and uniformity of process enables a wide range of systems on-chip applications and novel integration approaches including direct processing on organics, circuit cards, silicon photonic and III-V compound semiconductors, lithium niobate as well as enabling 3D integration stacking geometries that combine circuits with different nitride core thickness. A loss of 1.77 dB/m and intrinsic Q factor of almost 15 million for thin 80 nm thick core waveguides and low 8.66 dB/m loss with 4.03 million intrinsic Q for 800 nm thick core waveguides have been achieved. The thin core losses are over half an order of magnitude lower than previous low temperature processes, while our thick core devices have 39% more Q factor than previous thick silicon nitride low temperature processes with similar device area, while being 7.5 times smaller in area than the record high Q low temperature fabricated devices, having similar Q factors. The thin silicon nitride waveguides may be 5.36 cm long, almost 20× longer than the longest low temperature processed waveguide reported to date. Even though our silicon nitride seems to be slightly silicon-rich from the XPS measurements, the refractive indices, both linear and nonlinear, are much closer to that of previously measured values for stoichiometric silicon nitride.

Losses in the thin silicon nitride devices may be limited due to absorption loss from the unannealed lower cladding. In some embodiments, a SiO₂ layer may be deposited for the lower cladding utilizing deuterated silane. The small amount of hydrogen present in the deuterated silane precursor also increases the absorption loss as evidenced by the increase in waveguide loss towards 1520 nm which is near the 1st overtone of the SiN—H bond absorption. Towards 1630 nm, the loss increase is most likely due to overtones of the SiO-D bond in the upper cladding. These losses may be comparable to devices of the same geometry made with unannealed LPCVD silicon nitride confirming that the losses are competitive with respect to process temperature. At the same time, the more tightly confined modes in 800 nm thick devices with etched sidewalls have higher scattering losses than their thin nitride counterparts. In some embodiments, a hard mask with a smaller grain size such as those made with Atomic Layer Deposition (ALD) or RF sputtering may be used to etch the thicker devices which may limit scattering losses.

While the processing is described as occurring on a silicon wafer with a deposited lower cladding layer, it has been contemplated that the technique of depositing the patterned silicon nitride layer may be performed on a large variety of substrates thus enabling fabrication of ultra-low loss silicon nitride photonics on material systems not possible previously. Such material systems include III-V semiconductors, lithium niobate, preprocessed silicon circuits and photonics, and organic electronic materials. This makes these techniques applicable in technologies such as metrology, navigation, telecommunications, and quantum information sciences, and consumer electronics such as organic electronics. This process may be used to monolithically and homogeneously integrate both thin low confinement and thick high confinement silicon nitride waveguides, enabling 3D integration with optimized device footprint and linear and nonlinear performance. In some embodiments, the processing may be performed as low as 50° C. using further process development on ICP-PECVD tools which supports 50° C. processes. This may make this technique applicable for monolithic integration of ultra-low loss photonic integrated circuits on many more organic electronic materials.

In some examples, heterogeneous and monolithic integration of the versatile low loss silicon nitride platform with low temperature materials such as silicon electronics and photonics, III-V compound semiconductors, lithium niobate, organics, and glasses, has been inhibited by the need for high temperature annealing as well as the need for different processes for thin and thick waveguides. New techniques may provide state-of-the-art losses, nonlinear properties, and CMOS compatible process while enabling next level of 3D integration.

Many embodiments provide methods and processes for manufacturing ultra-low loss waveguides using temperatures less than about 250° C. Several embodiments can deposit oxides and/or nitrides in a manner where hydrogen is not introduced into the fabrication processes. In some embodiments, the oxides and/or nitrides can be deposited using temperatures less than about 250° C. in order to maintain low loss. The processes for fabricating waveguides in accordance with many embodiments can be desirable for CMOS and other advanced photonic and low-cost photonic applications. Several embodiments can reduce the cost and improve the manufacturability of integrated photonic and electronic-photonic circuits, and expand the applications to data centers, fiber communications, and precision visible applications including atomic clocks, quantum sensing and computing, precision metrology.

Various embodiments include significant advancements in silicon nitride integrated photonics, demonstrating an anneal-free process, with a maximum temperature 250° C., for an order of magnitude range in nitride thickness without requiring stress mitigation and polishing, using inductively coupled plasma-plasma enhanced chemical vapor deposition with a deuterated silane precursor gas. Various embodiments include 1.77 dB/m loss and 14.9 million Q for thin waveguides, over half an order magnitude lower loss than previous low temperature processes, and 8.66 dB/m loss and 4.03 million Q for thick nitride, the highest reported Q for a low temperature process with similar device area. The thick nitride devices include anomalous dispersion and over two-octave supercontinuum generation, from 650 nm to 2.7 μm, four-wave mixing parametric gain, and the lowest optical parametric oscillation threshold per unit resonator length of 15.2 mW/mm for a low temperature process. These devices include a significant step towards a uniform ultra-low loss silicon nitride homogeneous and heterogenous platform for both thin and thick waveguides capable of linear and nonlinear photonic circuits and integration with low temperature materials and processes.

Many embodiments provide fabrication methods for ultra-low loss waveguides including (but not limited to) silicon nitride waveguides, or silicon oxynitride waveguides, or tantala or silicon photonics. The fabrication processes use a temperature that is less than about 250° C. Several embodiments implement Inductively Coupled Plasma-Plasma Enhanced Chemical Vapor Deposition (ICP-PECVD) processes with deuterated silane as a precursor gas to grow materials including (but not limited to) silicon nitride, silicon oxide, and silicon oxynitride. Deuterated silane is silane that has the usual isotope of hydrogen replaced with deuterium. Deuterium is a stable isotope of hydrogen which is about twice as heavy as the usual isotopic of hydrogen. ICP-PECVD may also be referred to as Inductively Coupled Plasma Chemical Vapor Deposition (ICPCVD). ICP-PECVD utilizes inductive coupling to generate plasma. Thus, a voltage is applied to an inducive mechanism (e.g. coils) which may generate the plasma within the deposition chamber. There may be a separate accelerating voltage which may be referred to as a substrate bias. The accelerating voltage further accelerates the plasma. The accelerating voltage may be applied to the substrate. In conventional PECVD, there is a single voltage applied to both generate the plasma and accelerate the plasma. ICP-PECVD provides much more control over the quality of the deposited film than conventional PECVD. Further, ICP produces much more concentrated plasma power so that it can breakdown nitrogen gas (N₂) easily, which conventional PECVD cannot. This allows for pure nitrogen gas to be utilized as a precursor in ICP-PECVD but not in conventional PECVD. This is critical as in conventional PECVD, when depositing silicon nitride, ammonia (NH₃) is a typical precursor for a source of nitrogen which contains hydrogen. However, the added hydrogen may require an additional high temperature processing step to remove the hydrogen. Further, it has been discovered that ICP-PECVD also allows for deuterated silane to be used rather than typical silane. Deuterated silane includes deuterium instead of the typical hydrogen isotope. It has been found that deuterated silane provides substantially less hydrogenation of the resultant silicon nitride film. The resultant film when using nitrogen and deuterated silane precursors has less hydrogenation which may not require a subsequent dehydrogenation processing step. The dehydrogenation processing step may be an anneal process which typically occurs at 1150° C. or 1200° C. Utilizing ICP-PECVD for deposition of the silicon nitride layer and the subsequent upper cladding layer allows for the fabrication temperature to remain at or less than 250° C. which may open the possibility for a greater number of potential substrate types.

In various embodiments, the low temperature fabrication processes are compatible with various substrates comprising materials including (but not limited to) silicon, quartz, pre-processed silicon wafer, polymers, and III-V semiconductors. In many embodiments, the waveguide platforms can have any desired geometries. Examples of waveguides include (but are not limited to) high aspect ratio waveguides, thick waveguides, and square waveguides. In some embodiments, the waveguides can have a thickness from about 80 nm to about 800 nm; from about 100 nm to about 800 nm; from about 200 nm to about 800 nm; from about 300 nm to about 800 nm; from about 400 nm to about 800 nm; from about 500 nm to about 800 nm; from about 600 nm to about 800 nm; from about 20 nm to about 5 nm; greater than about 800 nm; greater than about 1 micron; greater than about 4 microns; from about 4 microns to about 5 microns; greater than about 5 microns; from about 5 microns to about 50 microns.

In several embodiments, the ultra-low loss waveguides fabricated with the low temperature process can have waveguide losses from about 0.9 dB/m to about 4 dB/m; or from about 0.9 dB/m to about 2 dB/m; or less than about 2 dB/m; in the wavelength range from about 1520 nm to about 1630 nm. In some embodiments, the ultra-low loss waveguides can have associated intrinsic resonator Qs from about 28 million to about 6 million in the wavelength range from about 1520 nm to about 1630 nm. A number of embodiments provide that the ultra-low loss waveguides have a low surface roughness.

The disclosed ultra-low loss silicon nitride photonic integrated circuits (PICs) can reduce the size, weight, and cost, and improve the reliability of a wide range of applications spanning the visible to infrared, including but not limited to quantum computing and sensing, atomic clocks, atomic navigation, metrology, and fiber optic communications as well as enabling new portable applications. In addition to replacing costly systems such as lasers and optical frequency combs that are relegated to bulky table-top systems, there is the potential to improve the performance for precision sciences, such as the frequency noise which is important for the manipulation and interrogation of atom, ions, and qubits. In this integration platform, by varying waveguide parameters such as nitride core thickness and optical confinement, it is possible to tradeoff characteristics such as loss, dispersion, nonlinearity, and device footprint to realize a wide range of linear and nonlinear components including ultra-low linewidth lasers, optical frequency combs, optical modulators, and atom and ion beam emitters.

The disclosure includes devices that are ultra-low loss and are fabricated utilizing wafer-scale CMOS foundry compatible processes which are maintained while uniformizing the processing of linear and nonlinear waveguides with the added functionality of gain, high bandwidth modulation, electronics, and engineered thermal properties, through heterogeneous integration with materials that cannot withstand high annealing temperatures, such as silicon photonic circuits, GaAs and InP semiconductor circuits, and nonlinear materials such as lithium niobate and tantalum pentoxide (tantala) as well as materials for thermal engineering such as quartz substrates. Previously, integration of these materials with both ultra-low loss thin and thick core nitride waveguides was inhibited by their incompatibility with the high temperature nitride growth and high-temperature post-oxide cladding annealing process that is used to achieve ultra-low losses. Additionally, integration was hindered by the fact that high performance thin and thick nitride waveguides use different fabrication processes with added process complexity to mitigate stress related issues in thick nitrides as well as costly chemical mechanical polishing (CMP). Disclosed herein are novel techniques that can provide the functionality of heterogeneous and monolithic integration to the silicon nitride platform without annealing, while maintaining the ultra-low loss advantage and provide the same wafer-scale processing steps for both thin and thick silicon nitride waveguides.

Various embodiments include heterogeneous and monolithic integration of ultra-low loss linear and nonlinear silicon nitride circuits. These embodiments may include a uniform anneal-free fabrication process that is compatible with a wide range of nitride core thickness, over an order of magnitude range (e.g. 20 nm to 800 nm), while maintaining the loss and other planar and high performance platform properties. State of the art thin (e.g. <100 nm) waveguide silicon nitride photonics achieve losses as low as 0.034 dB/m in the infrared and sub-dB/m losses in the visible. These losses may be achieved using Low Pressure Chemical Vapor deposited (LPCVD) silicon nitride core waveguides patterned on top of low absorption thermal silicon dioxide lower cladding, on silicon, and a Tetraethyl orthosilicate-plasma enhanced chemical vapor deposition (TEOS-PECVD) deposited fully annealed upper cladding, with other fabrication loss reduction techniques. The LPCVD nitride growth includes temperatures high temperature which may be as high as 850° C. A post process annealing temperature of 1150° C. may be utilized to drive out hydrogen from the LPCVD silicon nitride and the upper cladding, due to SiN—H bond absorption.

These post processing temperatures may be lowered which may yield less than 1 dB/m losses using an LPCVD nitride core annealed at 1050° C. with an unannealed deuterated upper cladding oxide. Other state of the art thick (e.g. >650 nm thickness) nitrides measure losses of 0.4 dB/m but include structures for stress mitigation, complicated chemical-mechanical polishing (CMP) steps, on top of annealing temperatures as high as 1050° C. similar to state-of-the-art thin nitrides. The losses in these thick nitride devices may be tightly coupled to the confinement factor and the device area. It is noted that in many previous devices, losses achieved using sputtered silicon nitride waveguide cores measure 2.4 dB/m at 1550 nm using an etchless liftoff techniques and 50 dB/m for etched nitride structures.

Various embodiments of the invention includes utilizing deuterated Inductively Coupled Plasma-Plasma Enhanced Chemical Vapor Deposition (ICP-PECVD) processes. Previous uses of ICP-PECVD processes for the nitride core have focused on 270° C. processes with thick core (>650 nm) high confinement waveguides for Kerr comb generation, as ICP-PECVD nitride exhibits less stress compared to LPCVD, achieving losses in the range of 6-30 dB/m and intrinsic Qs up to 5.3 million. These thicker processes do not explore low confinement thin (<100 nm) core waveguides in which the effect of scattering losses is reduced. ICP-PECVD based thick film nitride nonlinear resonators also show 1 THz free-spectral-range (FSR) 900 nm bandwidth modulation-instability microresonator Kerr combs and octave-spanning supercontinuum generation, with optical parametric oscillation (OPO) thresholds down to 13.5 mW and threshold per unit length down to 23.6 mW/mm. For heterogeneous and monolithic integration, it may be advantageous to limit the process temperature to under 400° C. Examples of advantages of this low processing include prevention of crystallization in low loss and nonlinear tantala waveguides, processing ultra-low loss waveguides directly on preprocessed silicon electronic or silicon photonic circuits, processing on thin film lithium niobate, and III-V semiconductors. Further, limiting the processing temperature to 250° C. enables a much broader class of heterogeneous and monolithic cointegration ultra-low loss thin and thick waveguide silicon nitride photonics with organic electronics, and directly processing on organic polymers like polyimide (e.g. Kapton) which are ubiquitous in consumer electronics, as the electrical and mechanical properties of these materials degrade exponentially and irreversibly above this temperature. Temperatures as low as 250° C. may also be beneficial to minimize thermal stress when processing on prepackaged electronics or on fragile substrates like quartz for athermalization.

While sputtering and conventional Plasma Enhanced Chemical Vapor Deposition (PECVD) can be done at low temperatures, both methods suffer from high particle counts, which cause high scattering losses, and conventional PECVD-grown silicon nitride may include high hydrogen content, due to utilizing precursors including hydrogen such as ammonia and silane precursors that causes high absorption losses. Various embodiments of the invention include Inductively Coupled Plasma—Plasma Enhanced Chemical Vapor Deposition (ICP-PECVD) with deuterated silane as a precursor gas, which may enable a lower temperature method to grow silicon nitride and silicon dioxide that eliminates absorption due to hydrogen bonds and has low particle counts. ICP-PECVD may utilize nitrogen gas instead of ammonia as a precursor to grow silicon nitride. The concentrated Inductively Coupled Plasma (ICP) power is able to dissociate N₂ which is not possible with conventional parallel plate PECVD.

Various embodiments include a process for producing ultra-low loss linear and nonlinear silicon nitride integrated photonics include ICP-PECVD which deposits silicon nitride with a lower hydrogen content than traditional PECVD deposition processes. This leads to an anneal-free fabrication process, with a maximum temperature for depositing oxide and nitride of 250° C. or less. This process may be utilized to fabricate waveguides an order of magnitude variation in thickness, 80 nm and 800 nm, without including complex steps such as stress mitigation and CMP. The maximum processing temperature used may be 20° C. lower than the lowest temperatures for making ultra-low loss waveguides. This temperature difference may be significant for processing organic materials which may not withstand high processing temperatures. The resultant integrated photonics may include a 1.77 dB/m loss with intrinsic Q factor of almost 15 million for thin 80 nm thick core waveguides. This is over half an order of magnitude lower loss than previous low temperature processes, and a record-low 8.66 dB/m loss with 4.03 million intrinsic Q factor for 800 nm thick core waveguides, 39% more Q factor as previous thick nitride low temperature process with similar device area while being 7.5 times smaller in area than the record high Q factor low temperature fabricated device, which has similar Q factors. The disclosed thin nitride waveguides may be 5.36 cm long, almost 20× longer than the longest low temperature processed waveguide reported to date.

The disclosed thick nitride waveguides and resonators may be included in various key nonlinear processes with the 800 nm nitride devices. For example, the photonic device may include resonant optical parametric oscillation (OPO) and Kerr-comb formation in microresonators and non-resonant supercontinuum generation in linear waveguides. Anomalous dispersion with over 2 octave supercontinuum generation may occur from 650 nm to 2.7 μm as well as four-wave mixing parametric gain with the near-lowest reported threshold of 16.7 mW for silicon nitride waveguides made with a low temperature process, and the lowest threshold per unit length of resonator of 15.2 mW/mm than the previous record for such a process. The waveguide losses are comparable with that of unannealed LPCVD nitride core waveguides of the same geometry and the shifted absorption peaks of 250° C. ICP-PECVD grown deuterated Si₃N₄ using Fourier transform infrared (FTIR) spectroscopy.

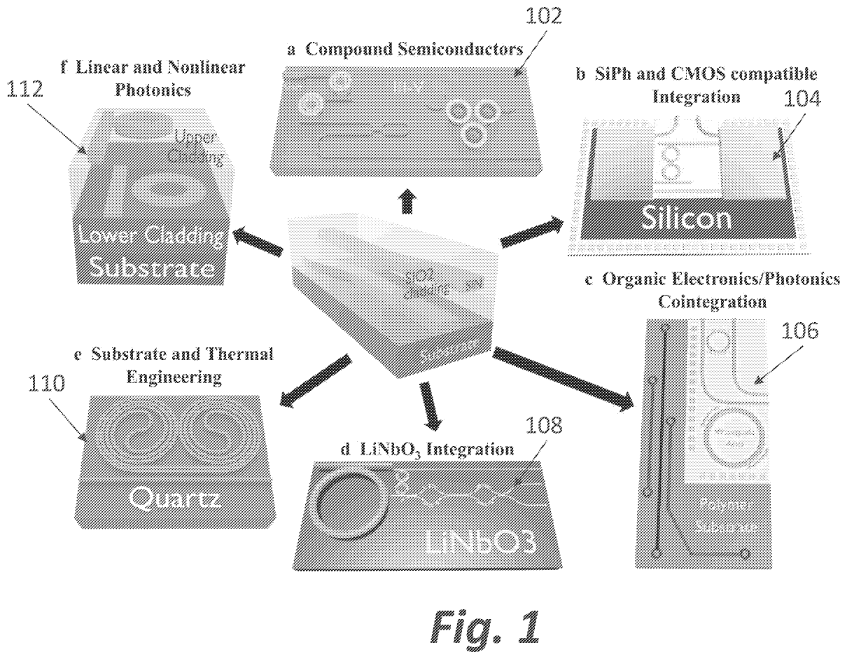

Various devices may be produced utilizing the disclosed processes which include heterogeneous and monolithic integration. FIG. 1 illustrates examples of different applications of different devices which may be produced. For example, the processes may be utilized in deposition of ultra-low loss waveguides on III-V semiconductors for high performance lasers and compound semiconductor photonic integrated circuits 102. Further, the processes may be used to preprocess electronic circuits and silicon photonics 104. Further, the processes may be utilized on organic material based integrated circuits 106 for cointegration with silicon nitride PICs and biophotonics. Further, the processes may be utilized on thin film lithium niobate 108 devices. The processes may be utilized on materials like quartz for athermalization of resonators and reference cavities 110. Additionally, the disclosed processes can be used to realize sophisticated multi-level silicon nitride photonic circuits 112, homogeneously and monolithically integrated with other materials, to combine high-performance thin-waveguide components like spectrally-pure Brillouin lasers and thick waveguide nonlinear components including optical frequency combs.

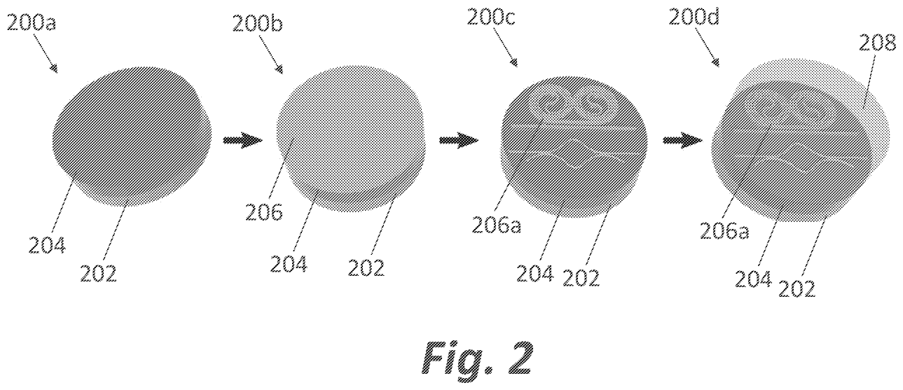

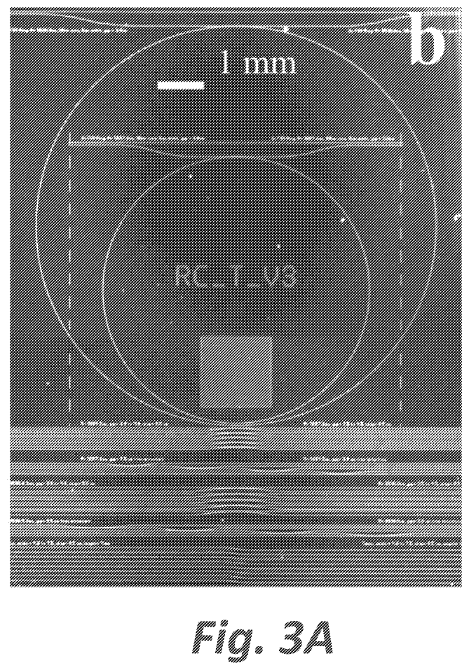

FIG. 2 is various stages of fabrication of a photonic device in accordance with an embodiment of the invention. A first step 200a includes providing a silicon wafer 202 with an oxide lower cladding 204. The silicon wafer may be 1 mm thick and the oxide lower cladding 204 may be a thermal oxide with thickness 15 μm. A second step 200b includes depositing a silicon nitride layer 206 on top of the thermal oxide lower cladding 204. The silicon nitride layer 206 may be a uniform silicon nitride layer. The silicon nitride layer 206 may be 80 nm or 800 nm. The silicon nitride layer 206 may be depositing using an ICP-PECVD process. The ICP-PECVD process may include a deuterated silane pre-cursor. The ICP-PECVD process may occur at 250° C. A third step 200c may include patterning the silicon nitride layer 206 into patterned silicon nitride 206a. The patterning may be performed using an etching process such as Inductively Coupled Plasma Reactive Ion Etcher (ICP-RIE) etching. ICP-RIE may be performed at 50° C. A fourth step 200d may include depositing a silicon dioxide cladding layer 208 over the patterned silicon nitride 206a. Depositing the silicon dioxide cladding layer 208 may occur utilizing an ICP-PECVD process. The ICP-PECVD process may include a deuterated silane pre-cursor. The ICP-PECVD process may occur at 250° C.

In some embodiments, the lower cladding 204 may be deposited on the silicon wafer 202 using an ICP-PECVD process with the silicon nitride layer 206 and the silicon dioxide cladding layer 208.

The silicon nitride layer 206 and the silicon dioxide cladding layer 208 may be deposited using an Unaxis VLR ICP-PECVD or a similar ICP-PECVD machine.

The ICP-PECVD deposition process may utilize deuterated silane having an isotropic purity of about 98%. During the nitride deposition, the deuterated silane, nitrogen, and argon may flow at about 12.5, 8, and 20 SCCM respectively, at a RF power of about 800 W, at a temperature of about 250° C., and at a pressure of about 5 mT. Before the actual process step of deposition, a seasoning step may be performed. In some embodiments, before depositing the nitride on a device wafer, some film is deposited on a test wafer to count the number of particles, and measure the deposition rate and refractive indices. The test wafer may then be used to measure the surface roughness of the film, the film stress, as well as the etch rate of the silicon nitride in buffered HF solution—as a proxy for its optical quality.

The test deposition may be run on a test silicon wafer to deposit a test layer. A measurement of particle count of this deposition may be performed with a particle count machine (e.g. KLA/Tencor Surfscan), as well as the film thickness and refractive index with an ellipsometer (e.g. a Woollam Ellipsometer). The deposition on the device wafer may be performed only if the particle counts increase by less than 300. The test layer may be measured to have a certain refractive index (e.g. 1.95) at 1550 nm using an ellipsometer. The particle counts for particles of diameters between 160 nm to 1.6 μm on the film, over a 100 mm wafer, may be checked to be below a certain number (e.g. less than 100). The nitride film etched at a rate of about 6.3 nm/min in a Transene UN2817 buffered HF solution, and the deposition rate of the film in the ICP-PECVD tool is about 42 nm/min using the ellipsometer. For a 336 nm nitride film on a 0.5 mm thick silicon substrate, the compressive stress is about 666 MPa.

The ICP-PECVD process may deposit the silicon nitride layer 206 at 250° C. on the silicon wafer 202 with the oxide lower cladding 204. The lower cladding may have thickness of 15 μm. A longer cycle may be run to deposit a thicker silicon nitride layer 206 where a thicker silicon nitride layer is desired. In some embodiments, for a thicker silicon nitride layer 206, Ruthenium (Ru) may be sputtered at a thickness of 40 nm direct current on top of the silicon nitride layer 206 to form a hard mask layer. A thin silicon nitride layer may be thickness less than 200 nm. In some examples, a thin silicon nitride layer may have a thickness between 40 nm and 175 nm.

A thick silicon nitride layer may be thickness greater than or equal to 200 nm. In some embodiments, a thick silicon nitride layer may include a thickness between 200 nm and 800 nm. While specific examples are described with relation to thick and thin silicon nitride layers, in some embodiments, the thickness of the silicon nitride can be between 5 nm and 20 nm and between 1 micron and 2 microns with maximum process temperature of 250° C.

After depositing the silicon nitride layer 206, as illustrated in step 3, the silicon nitride layer is patterned. The patterning may be performed utilizing a 248 nm Deep UV (DUV) stepper. A photoresist may be utilized to perform the patterning where a photoresist is deposited onto the unetched silicon nitride layer 206 and then patterned utilizing the stepper. The exposed photoresist may be developed to provide a patterned photoresist. In some embodiments, a hard mask process may be performed where a hard mask is deposited onto the unetched silicon nitride layer 206 and a pattern is etched into the hard mask which is used to pattern the silicon nitride layer 206.

In some embodiments, when the silicon nitride layer 206 is a thin silicon nitride layer, an Inductively Coupled Plasma (ICP-RIE) may be used to etch the silicon nitride layer 206 into the patterned silicon nitride 206a. The ICP-RIE may use a CF₄/CHF₃/O₂ chemistry. After the CF₄/CHF₃/O₂ chemistry, an ashing step of a 02 plasma in a Inductively Coupled Plasma (ICP) tool may be used to remove etch byproducts. After etching the silicon nitride layer 206, the remaining photoresist may be stripped by sonicating in a hot N-methyl-2-pyrrolidone (NMP) solution and rinsing in isopropanol. A piranha clean at 100° C. may be additionally perform followed by a piranha clean at 70° C., making the thin nitride wafers ready for upper cladding deposition.

In some embodiments, when the silicon nitride layer 206 is a thick silicon nitride, the Ru on the thick nitride etched using a Cl₂/O₂ chemistry to create a hard mask. The photoresist may then be stripped using the same process as with the thin silicon nitride layer, using a hot NMP solution and isopropanol. Then, an ICP-RIE etching process using CF₄ only may be used, after which the same 02 plasma ashing as the thin nitrides is performed. Any remaining Ru may be stripped in a wet etch, and then the same piranha clean may be performed as with the thin silicon nitride layers.

After the piranha cleans for both the thin silicon nitride layer and the thick silicon nitride layer, an ICP-PECVD SiO₂ upper cladding may be deposited at 250° C.

In some embodiments, the device includes multiple layers of alternating waveguide and cladding layers with interconnecting layers which are grown with a maximum processing temperature of 250° C. These multiple alternating layers may include the silicon nitride layers which may be utilized as waveguides which are fabricated with ICP-PECVD processes discussed above and cladding layers which are fabricated with ICP-PECVD processes discussed above.

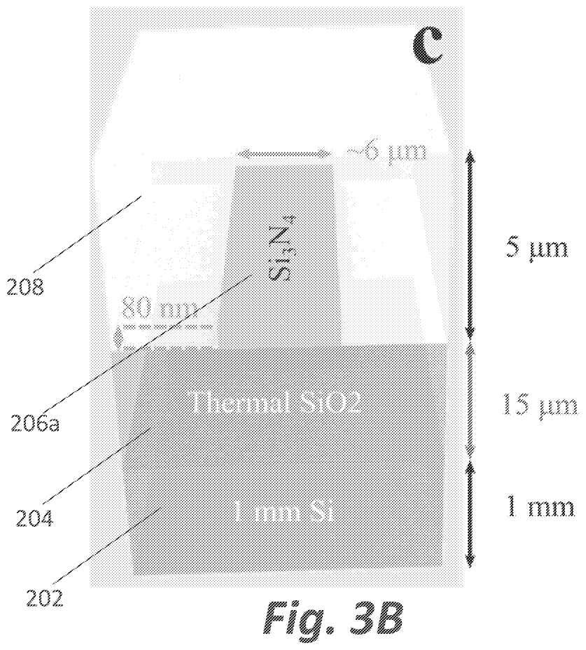

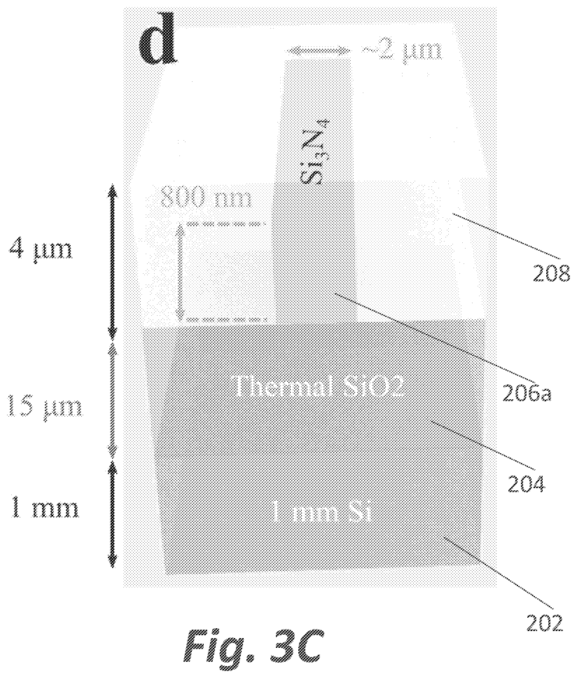

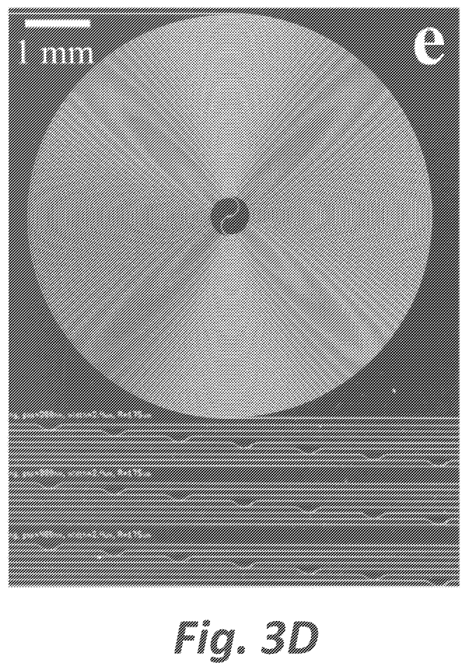

FIG. 3A is a top down photograph of a patterned silicon nitride layer 206a on the silicon dioxide cladding layer 208 manufactured with the process described in connection with FIG. 2.

FIG. 3B is a schematic perspective view of an example photonic device manufactured with the process described in connection with FIG. 2. The patterned silicon nitride 206a may be 6 μm wide and 80 nm thick. The patterned silicon nitride 206a may be a Si₃N₄ waveguide core. The lower cladding layer 204 may be 15 μm thick thermal oxide SiO₂. The upper cladding layer 208 may be 5 μm thick ICP-PECVD oxide. The patterned silicon nitride 206a may be utilized as the ring and bus waveguide of a ring shaped resonator. The ring shaped resonator may have a bus-ring coupling gap of 3.5 μm and the ring radius of 8530.8 μm. The ring-shaped resonator may support one quasi-transverse electric (TE) TE mode and one quasi-transverse magnetic (TM) mode for all of the process variations.

The photonic device may include a thick silicon nitride layer. FIG. 3C is a schematic perspective view of an example photonic device manufactured with the process described in connection with FIG. 2. The patterned silicon nitride 206a may be a thick nitride core of thickness 800 nm. The lower cladding layer 204 may be a thick SiO₂ thermal oxide with a thickness of 15 μm. The upper cladding layer 208 may be an ICP-PECVD oxide layer of thickness 4 μm. For nonlinear applications the waveguides and resonators may include low parametric oscillation threshold, including parameters such as high extinction ratio, high intrinsic Q factors, and small modal area. The patterned silicon nitride 206a may include a waveguide width of 2 μm. The device may include a 300 nm ring-to-bus waveguide gap.

FIG. 3D is a top down photograph of an example patterned silicon nitride 206a on the silicon dioxide cladding layer 208 manufactured with the process described in connection with FIG. 2. The waveguide widths may be between 1.4 and 2.4 μm for both the ring resonator and bus waveguides. The ring radii may be between 165 and 177 μm. The ring-bus coupling gaps may be between 200 and 600 nm. The spirals may be of length of up to 35 cm.

The photonic device may include a buried silicon nitride core channel waveguide that has over an order of magnitude variation in nitride core thickness. The process independence with respect to waveguide thickness may provide co-integration of thin and thick nitride core devices and 3D monolithic and homogeneous integration as well as monolithic and heterogeneous integration on a variety of other platforms.

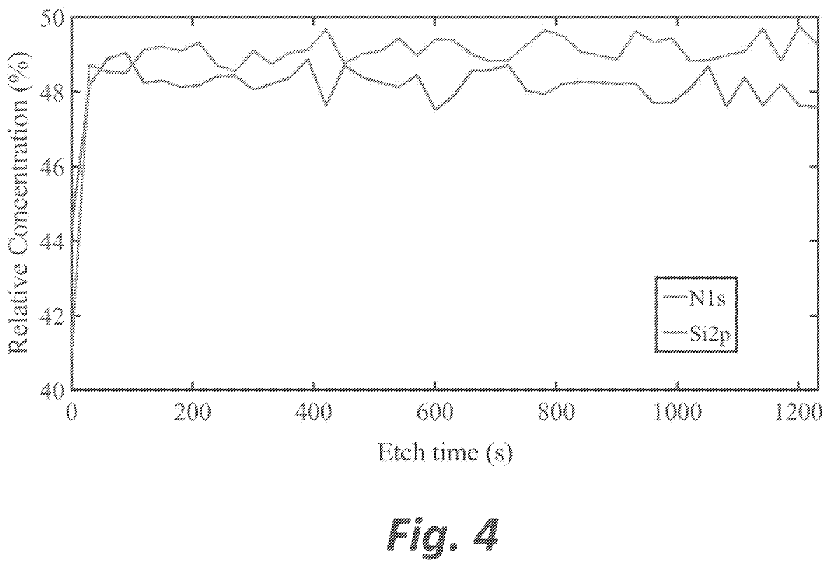

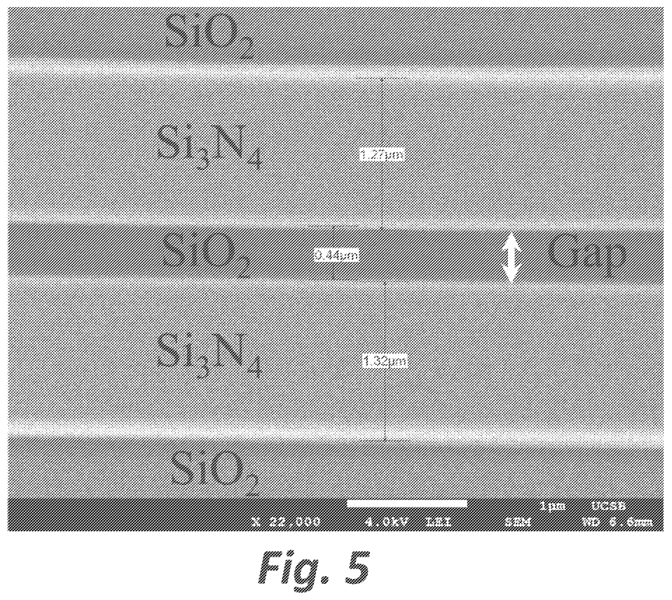

The absorption and composition of the deposited silicon nitride were characterized using FTIR and X-ray Photoelectron Spectroscopy (XPS). FIG. 4 illustrates a SiN X-ray photoelectron spectroscopy (XPS) measurement. The XPS measurements of the nitride film show that there may be 25% more nitrogen deficient than stoichiometric silicon nitride.

FIG. 5 is a top-down Scanning Electron Microscopy (SEM) image of a fabricated ring resonator near the coupling gap before upper cladding deposition. The patterned silicon nitride may have a thickness of 800 nm with a width of 1.4 μm. The patterned silicon nitride may be patterned utilizing a mask having gaps of 400 nm on mask. The measured gaps after patterning may be 0.44 μm and the patterned silicon nitride waveguide widths of adjacent waveguides may be 1.32 μm and 1.27 μm.

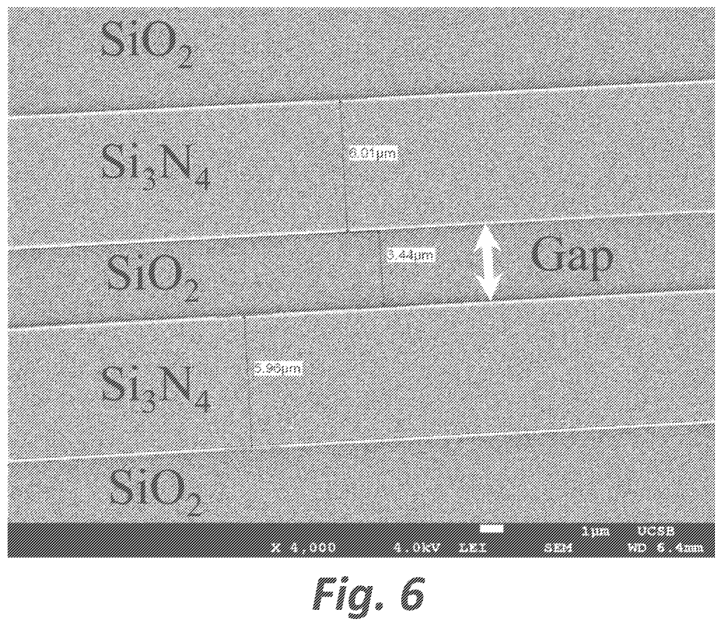

FIG. 6 is a top-down SEM image of a fabricated ring resonator. The patterned silicon nitride has a thickness of 80 nm with a width of 6 μm. The patterned silicon nitride may be patterned using a mask with gaps of 3.5 μm. The measured gap after patterning may be 3.44 μm, and the widths of the patterned silicon nitride waveguide widths 6.01 and 5.96 μm respectively. There are no signs of abnormalities in the etched 800 nm thick film as illustrated in FIG. 5 as well the thin nitride devices as illustrated in FIG. 6.

The losses and Q factors may be calculated by measuring resonances using a calibrated Mach Zehnder interferometer (MZI) technique, for the fundamental Transverse Magnetic (TM) modes only. For each resonator design, 3 different devices were characterized, and these measurements were repeated for all devices from 1520 and 1630 nm in steps of 10 nm for the TM mode only.

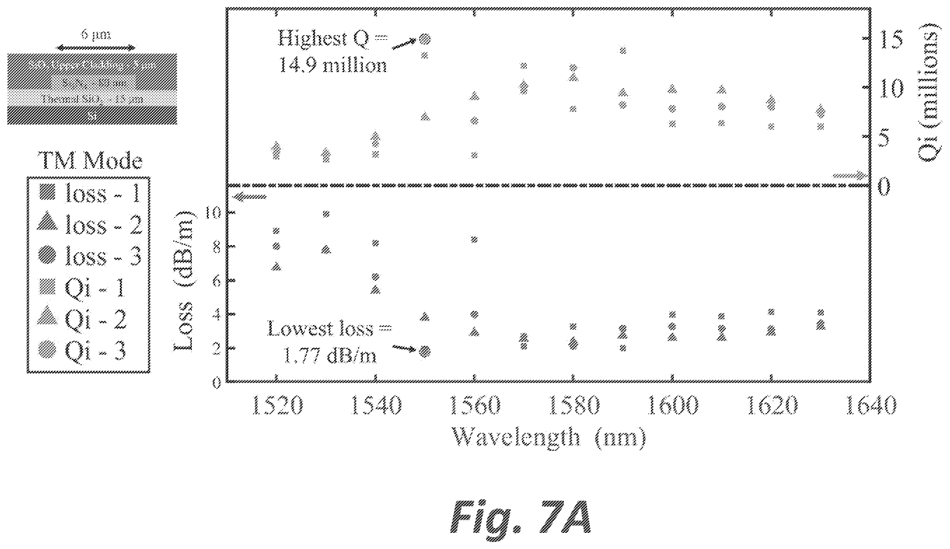

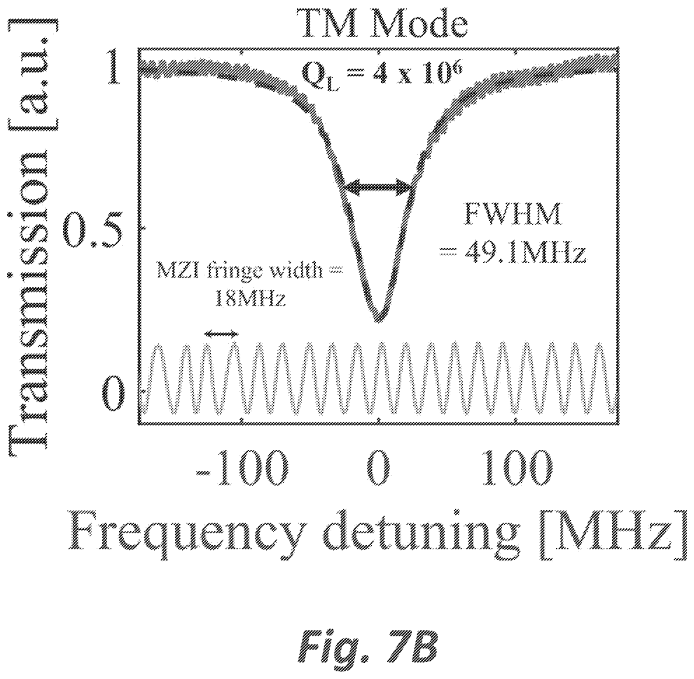

FIG. 7A is various plots illustrating TM mode loss and intrinsic Q variation vs wavelength for 3 different devices. FIG. 7B are various plots illustrating Transverse Magnetic (TM) mode resonance Q measurement. For the TM mode, losses are measured at 1550 nm down to 1.77 dB/m for an intrinsic Q of 14.9 million from an over-coupled resonance with a loaded Q of 4.0 million and FWHM of 49.1 MHz. The median of the intrinsic Q and loss for the TM mode throughout the above wavelength ranges measured is 7.77 million and 3.26 dB/m respectively, while the average intrinsic Q and loss were 7.55 million and 4.31 dB/m respectively.

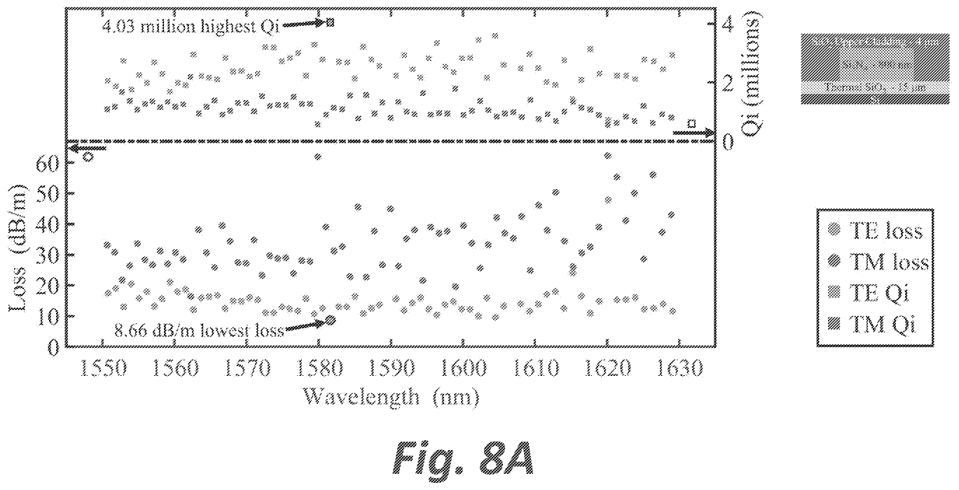

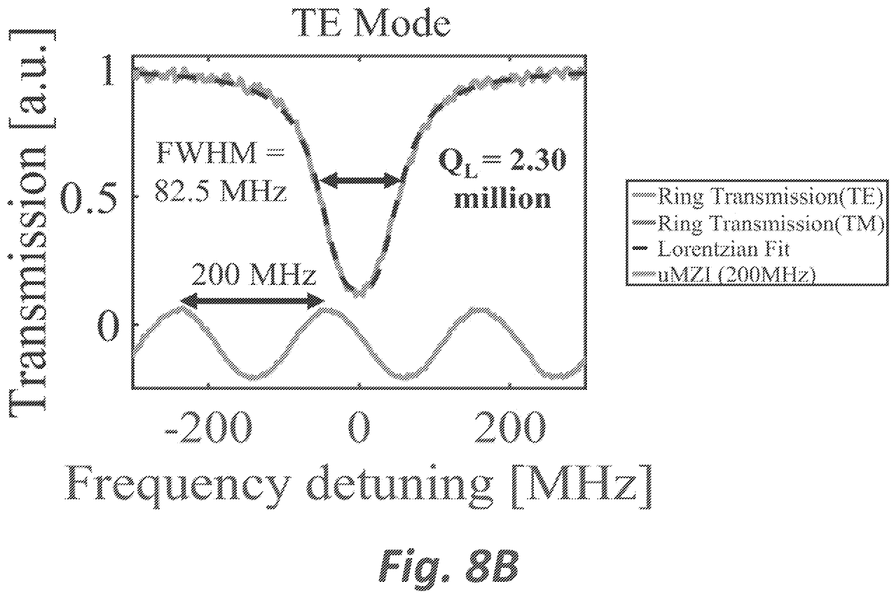

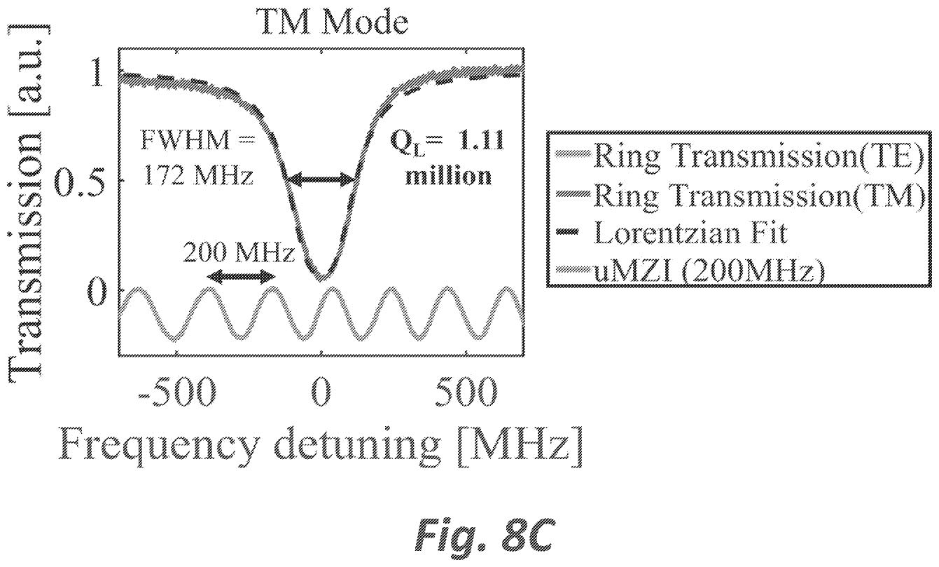

The same calibrated MZI method may be used to measure the loss and Q for a 800 nm nitride ring resonator between 1550 nm to 1630 nm. FIG. 8A is various plots of loss and intrinsic Q variation vs wavelength for the Transverse Electric (TE) and Transverse Magnetic (TM) modes. FIG. 8B is various plots of TE mode resonance Q measurement at 581 nm. FIG. 8C is various plots of TM mode resonance Q measurement at 1560 nm. All measurements are for 175 μm radius ring resonators with 2 μm wide waveguides. Example measured resonances for this 2 μm wide waveguide with 175 μm radius ring resonator is shown in FIGS. 8B and 8C for the TE and TM modes yielding losses as low as 8.66 dB/m and 16.4 dB/m for the modes respectively, and intrinsic Qs as high as 4.03 million and 2.19 million for the TE and TM respectively. The loaded Qs of these TE and TM modes were 2.30 million and 1.11 respectively, with FWHMs of 82.5 MHz and 172 MHz respectively.

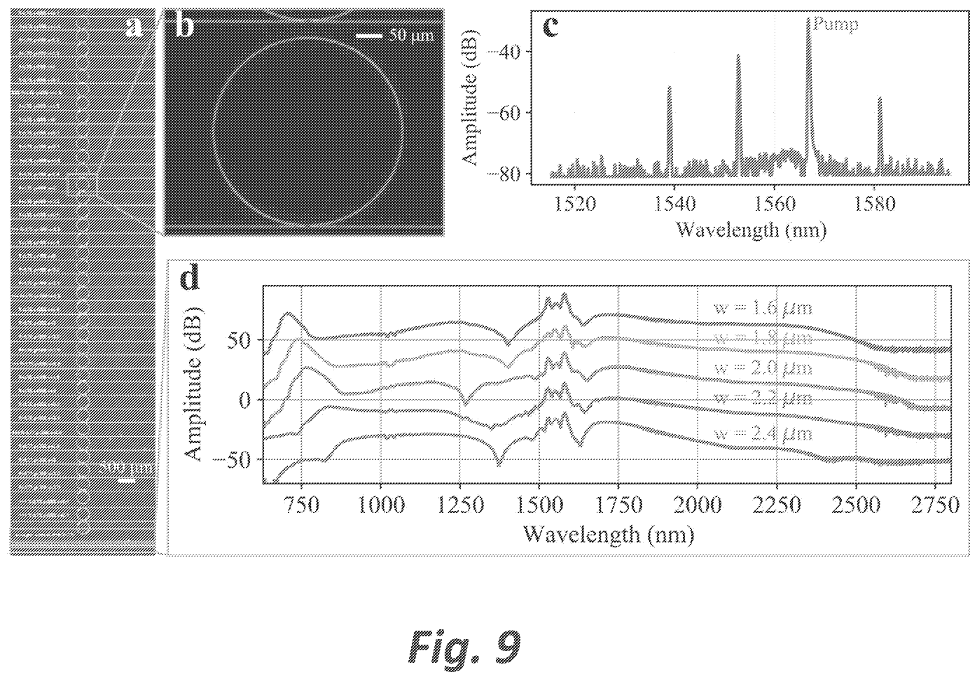

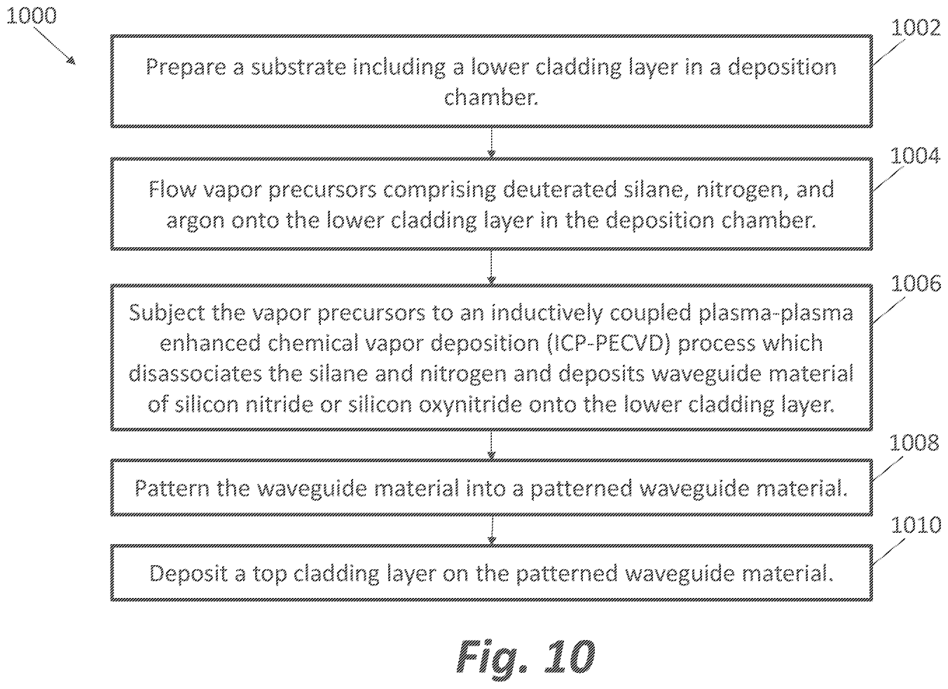

Nonlinear integrated photonics may be important in technologies including next-generation optical atomic clocks, next-generation telecommunications sources and data communications, trace gas sensing, and quantum computing. Nonlinear photonic waveguides with wavelength-scale dimensions (e.g. ˜1 μm) offer the high optical confinement needed to increase the effective nonlinearity. Additionally, the high confinement allows for geometric tuning of the waveguide dispersion and arbitrary control of phase matching. FIG. 9 illustrates example nonlinear application results of thick 800 nm waveguides and resonators. FIG. 9(a) is a large field of view image of a thick nitride chip with a broad scan of ring resonator designs and straight waveguides. The green and blue highlighted regions correspond to devices tested in FIG. 9(c) and FIG. 9(d). FIG. 9(b) is a dark-field optical micrograph of the ring resonator device used for Kerr-comb measurement. FIG. 9(c) is an optical spectrum of the ring resonator output showing the onset of optical parametric oscillation. FIG. 9(d) is a broadband supercontinuum spectra from the 2.2 μm width waveguide resonator highlighted in light blue in FIG. 9(a). Two key nonlinear processes with the 800 nm silicon nitride waveguides and resonators illustrated FIG. 9(a) and FIG. 9(b) are present. Resonant optical parametric oscillation (OPO) and Kerr-comb are formed in microresonators. Non-resonant supercontinuum are generated in linear waveguides.

FIG. 9(b) illustrates OPO and Kerr-comb formation in a 175 μm radius microring resonator with cross-sectional dimensions of 800×2000 nm, for a resonance at 1566.7 nm with Q_{L}˜ 1.6 million and Q 2.0 million. FIG. 9(c) shows OPO at a low on-chip pump power of 25 mW. As the pump power is increased, Turing pattern formation modulation-instability comb states are also observed. A threshold power, Pₜₕ, for OPO of ˜16.7 mW corresponding to an effective nonlinear index, n₂˜1.5×10⁻¹⁹ m²/W which is only slightly lower than measurements of n₂ for stoichiometric nitride devices, as well as the lowest threshold power per unit length of 15.2 mW/mm for any low temperature silicon nitride process.

FIG. 9(d) illustrates broadband supercontinuum generation in 4 mm long, 800 nm thick, straight waveguides with widths ranging from 1.6 to 2.4 um. The supercontinuum spectra may be provided by coupling light from a 1550 nm, 100 MHz repetition rate mode-locked laser with 100 fs pulse duration and on-chip pulse energies ˜200-400 pJ for the waveguides. The resulting supercontinuum emission covers two octaves, from ˜650 nm to ˜2.7 μm. CO2 absorption lines in the spectrum analyzer are evident at the long wave side of the spectrum. While the dispersion of these devices is not favorable for mid-infrared supercontinuum generation, absorption spectra of the disclosed deuterated nitride and oxide layers and these devices support waveguiding and supercontinuum generation out to 4 μm.

The loaded quality factors of the ring resonators were measured using three different calibrated unbalanced fiber MZIs with MZI fringe widths of 5.87 MHz, 18 MHz, and 200 MHz. Two Newport Velocity TLB-6700 tunable lasers were used, one with a tuning range of 1520 to 1570 nm, and another one with a tuning range from 1550 to 1630 nm. These lasers were tuned in wavelength with piezo actuators, by applying a ramp signal to the same. A polarization controller may be provided before the input for the thin silicon nitride devices, which is edge-coupled to a single mode cleaved fiber, while there may be a polarization beam splitter present before the input to the thick silicon nitride devices. Loaded and intrinsic quality factors may be extracted by fitting the resonance transmission to a Lorentzian (thin nitride) or coupled-Lorentzian (thick nitride) curves. Coupling and loss parameters may be determined by measuring the ring-to-bus couplings on independent ring-bus coupling structures as well as simulating the same.

The effective nonlinear index for the deuterated silicon nitride may be determined by measuring the threshold power for OPO, Pth, according to the following:

$${n}_{2} = \frac{π n {v}_{0} {A}_{eff}}{8 {P}_{th} {v}_{FSR} {Q}_{i}^{2}} \frac{{( 1 + K )}^{3}}{K}$$

where n is the effective refractive index, A_{eff} is the effective mode area, v_{FSR}=133.5 GHz is the resonator free spectral range, vₒ is the pump frequency, Qᵢ is the resonator intrinsic Q, and K is a resonator coupling constant K=Qᵢ/Q_{c}, where Q_{c} is the resonator coupling Q. Values of Qᵢ and Q_{c} may be extracted through the Lorentzian curve fitting method described above. The software Lumerical MODE may be utilized to calculate A_{eff} and n as a function of wavelength (in this case 1.35 μm² and 1.85 respectively). Based on the analysis, n₂˜1.5±0.2×10⁻²⁰ m²/W. Measurement uncertainty may be propagated from measurement resolution of the threshold power and the one standard deviation error of the curve fitting parameters which determine Q values.

Turning back to the figures, FIG. 10 illustrates a method 1000 for fabricating an ultra-low loss waveguide. The method 1000 includes preparing (1002) a substrate including a lower cladding layer in a deposition chamber. The substrate may include silicon, quartz, a III-V semiconductor, or a polymer. The lower cladding layer may include silicon oxide (SiO₂). The lower cladding layer may be deposited on the substrate. Depositing the lower cladding layer may include flowing vapor precursors of deuterated silane, oxygen, and argon onto the lower patterned waveguide material and subjecting the vapor precursors to an ICP-PECVD process which disassociates the silane and oxygen and deposits waveguide material of silicon oxide onto the substrate. The oxygen may be oxygen gas or molecular oxygen (O₂).

The method 1000 further includes flowing (1004) vapor precursors including deuterated silane, nitrogen, and argon onto the lower cladding layer in the deposition chamber. The nitrogen may be nitrogen gas and/or molecular nitrogen (N₂) The method 1000 further includes subjecting (1006) the vapor precursors to an inductively coupled plasma-plasma enhanced chemical vapor deposition (ICP-PECVD) process which disassociates the silane and nitrogen and deposits waveguide material of silicon nitride or silicon oxynitride onto the lower cladding layer. Advantageously, the ICP-PECVD process occurs at a temperature less than or equal to 250° C.

The method 1000 further includes patterning (1008) the waveguide material into a patterned waveguide material. Patterning 1008 the waveguide material may be different for different thicknesses of waveguide materials. For thick waveguide material, it may be advantageous to pattern the waveguide material with a hard mask. A thick waveguide material may include a waveguide material of thickness less than 200 nm. In some embodiments, the thickness of the waveguide material may be 800 nm.

In this instance, patterning 1008 the waveguide material includes: depositing a hard mask layer on the waveguide material; coating the hard mask layer with a photoresist; exposing the photoresist through a mask to transfer a pattern onto the photoresist; etching the hard mask layer through the photoresist; removing the photoresist; etching the waveguide material through the hard mask layer; and removing the hard mask layer.

In thin waveguide material, it has been discovered that thin waveguide material may be patterned without a hard mask. A thin waveguide material may include a waveguide material of thickness less than 200 nm. In some embodiments, the thin waveguide material may be a thickness between 40 nm and 175 nm. In some embodiments, the thickness of the waveguide material may be 80 nm. In these instances, patterning 1008 the waveguide material may include coating the waveguide material with a photoresist; exposing the photoresist through a mask to transfer a pattern onto the photoresist; etching the waveguide material through the photoresist; and removing the photoresist.

The method 1000 further includes depositing (1010) a top cladding layer on the patterned waveguide material. Depositing 1010 the top cladding layer may include flowing vapor precursors of deuterated silane, oxygen, and argon onto the lower patterned waveguide material and subjecting the vapor precursors to an ICP-PECVD process which disassociates the deuterated silane and oxygen and deposits waveguide material of silicon oxide onto the patterned waveguide material. The oxygen may be oxygen gas or molecular oxygen (O₂).

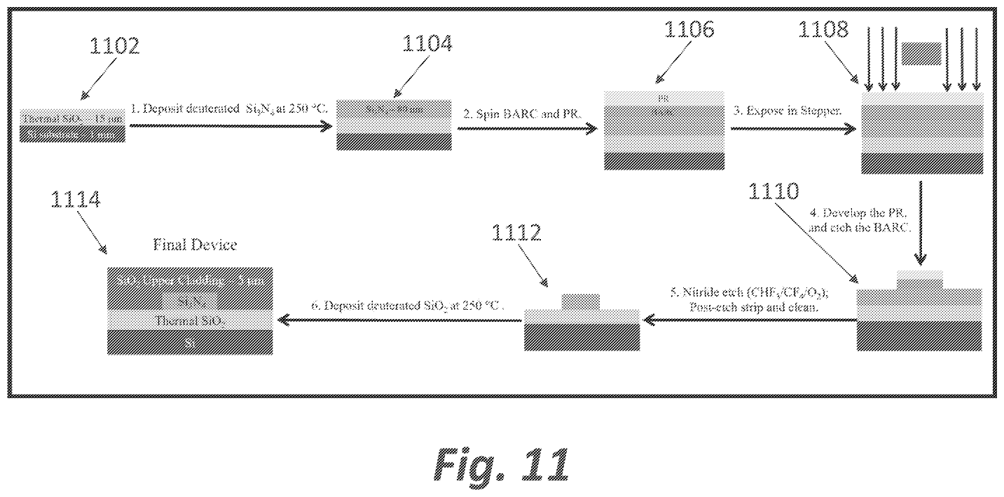

FIG. 11 is a flow chart of an example method of manufacturing a thin silicon nitride waveguide. In a first step 1102, a silicon substrate with a thermal oxide lower cladding layer is provided. In a second step 1104, a silicon nitride layer is deposited on the lower cladding layer. The silicon nitride layer may be deposited utilizing an ICP-PECVD process as discussed above. In a third step 1106, a layer of photoresist (PR) and bottom anti-reflective coating (BARC) is coated on the silicon nitride layer. In a fourth step 1108, the PR and BARC are exposed. The exposure may be performed with a stepper. In a fourth step 1110, the PR is developed and the BARC is etched. In a fifth step 1112, the silicon nitride layer is etched to form the silicon nitride waveguide. In a sixth step 1114, an upper cladding layer is deposited on the silicon nitride waveguide to form the final device.

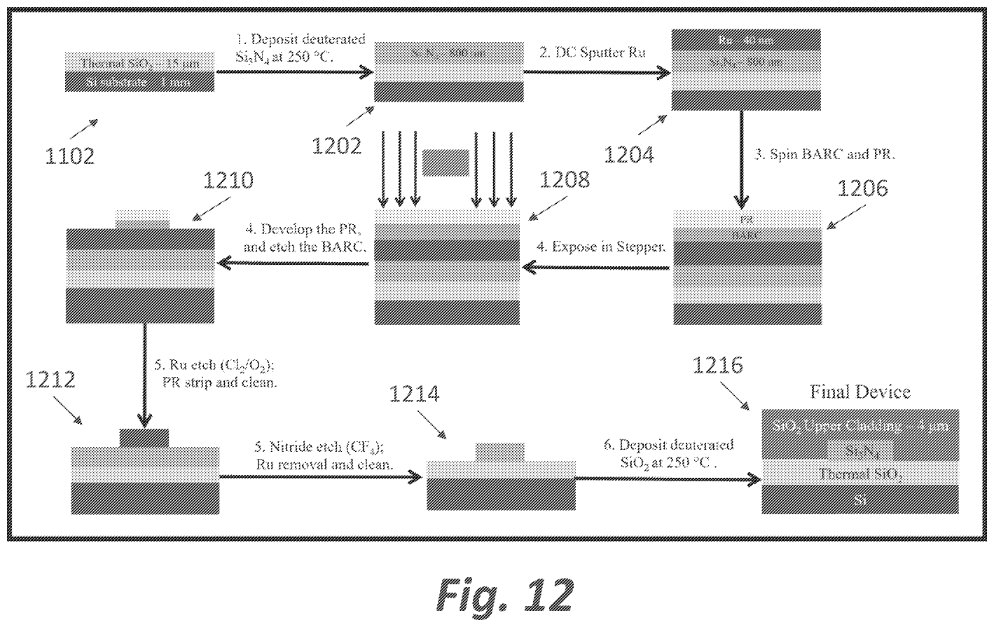

As discussed above, a hard mask may be utilized in manufacturing a thick silicon nitride waveguide. A thick waveguide material may include a waveguide material of thickness greater than or equal to 200 nm. In some embodiments, the thick waveguide material may have a thickness between 200 nm and 800 nm. FIG. 12 illustrates an example method of manufacturing a thick silicon nitride waveguide. Similar to the example method described in FIG. 11, in a first step 1102, a silicon substrate with a thermal oxide lower cladding layer is provided. In a second step 1202 a thick silicon nitride layer is deposited. The silicon nitride layer may be deposited utilizing an ICP-PECVD process as discussed above. Dissimilarly to the process of FIG. 11, in a third step 1204, a hard mask layer is sputtered onto the silicon nitride layer. Steps 1206, 1208, 1210, and 1212 substantially mirror steps 1106, 1108, 1110, and 1112 of FIG. 11, except the hard mask layer is etched in step 1212 as opposed to the silicon nitride layer being etched in step 1112. In step 1214, the hard mask is utilized to etch the silicon nitride layer into a silicon nitride waveguide. In step 1216, an upper cladding layer is deposited on the silicon nitride waveguide to form the final device. The silicon nitride waveguide may be buried in the upper cladding layer in the final device.

It has further been discovered that even thicker waveguide materials may benefit from an additional silicon oxide hard mask layer above the Ru layer. For example, in the process for manufacturing a thick silicon nitride waveguide including a thickness greater than 800 nm, the manufacturing steps described in connection with FIG. 12 apply, except in the third step 1204 an additional hard mask layer of silicon oxide is deposited above the hard mask layer (e.g. Ru layer).

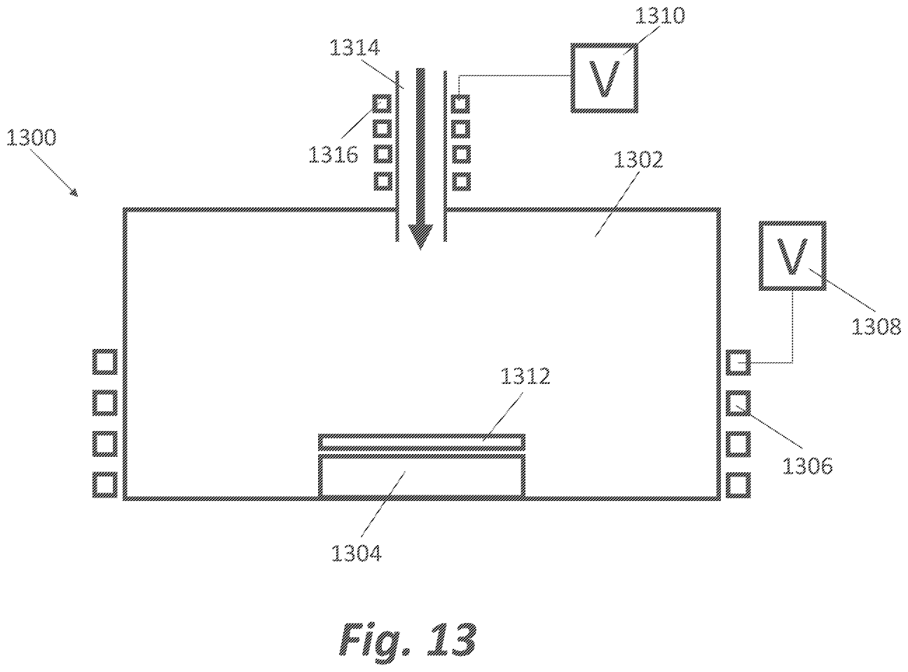

FIG. 13 is a cross-sectional schematic of an example ICP-PECVD apparatus 1300. The ICP-PECVD apparatus 1300 includes a deposition chamber 1302 which houses a substrate holder 1304 which is configured to support a substrate 1312. A gas inlet 1314 is configured to input gas into the deposition chamber 1302. Inductive coils surround the gas inlet 1314. Inductive coils 1306 also surround the deposition chamber 1302.

When gas is input into the deposition chamber 1302 through the gas inlet 1314, a plasma producing voltage 1310 is applied to the inductive coils 1316 surrounding the gas inlet 1314 which produces plasma. Advantageously over conventional PECVD apparatuses, different precursors may be used due to the high ionizing power of the inductive coils 1316. A separate accelerating voltage 1308 may be applied to the inductive coils surrounding the deposition chamber 1302 which may accelerate the plasma towards the substrate 1312 and deposit a layer onto the substrate. The ICP-PECVD apparatus deposits high purity films over the substrate 1312 at low temperatures. These films may be substantially free of hydrogen and thus may not benefit from a separate annealing/processing step to remove hydrogen from the films. Due to the plasma producing voltage 1310 applied to the inductive coils 1316 surrounding the gas inlet 1314, different precursors may be utilized from what is used in conventional PECVD apparatuses. For example, the precursors may include molecular gases (e.g. nitrogen gas or oxygen gas) instead of the same elements of the molecular gases combined with hydrogen (e.g. ammonia or water). Further, the precursors may include deuterated silane which disassociates into a purer form of silicon (Si) without including hydrogen.

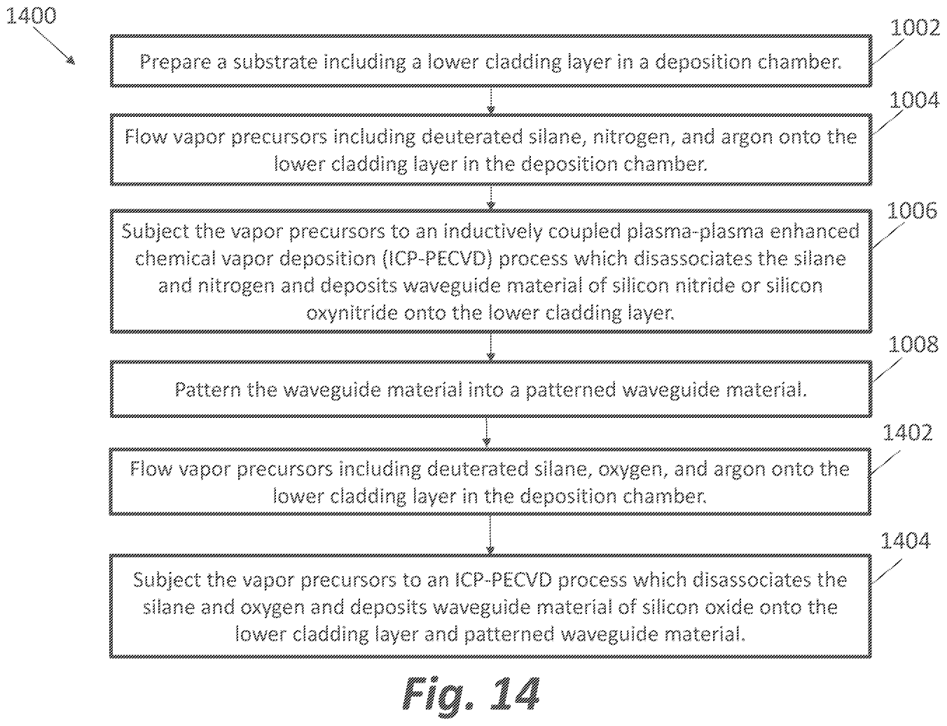

FIG. 14 is a flow chart of an example method of manufacturing 1400 a thin silicon nitride waveguide. Many identically numbered steps are the same as is described in FIG. 11. These descriptions are applicable in this method and will not be repeated. The method 1400 further includes flowing (1402) vapor precursors including deuterated silane, oxygen, and argon onto the lower cladding layer in the deposition chamber. The method further includes subjecting (1404) the vapor precursors to an ICP-PECVD process which disassociates the silane and oxygen and deposits waveguide material of silicon oxide onto the lower cladding layer and the patterned waveguide material. Utilizing ICP-PECVD allows the use of precursors such as deuterated silane and molecular oxygen which allows for low temperature deposition of substantially hydrogen free silicon oxide. This silicon oxide layer does not require an additional dehydrogenation processing step.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately,” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to +0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

### Doctrine of Equivalents

As can be inferred from the above discussion, the above-mentioned concepts can be implemented in a variety of arrangements in accordance with embodiments of the invention. Accordingly, although the present invention has been described in certain specific aspects, many additional modifications and variations would be apparent to those skilled in the art. It is therefore to be understood that the present invention may be practiced otherwise than specifically described. Thus, embodiments of the present invention should be considered in all respects as illustrative and not restrictive.

What is claimed is:

1. A method for fabricating an ultra-low loss waveguide comprising:
preparing a substrate including a lower cladding layer in a deposition chamber;
flowing precursors comprising deuterated silane and nitrogen onto the lower cladding layer in the deposition chamber;
subjecting the precursors to an inductively coupled plasma-plasma enhanced chemical vapor deposition (ICP-PECVD) process which disassociates the deuterated silane and nitrogen and deposits waveguide material of silicon nitride or silicon oxynitride onto the lower cladding layer;
patterning the waveguide material into a patterned waveguide material; and
depositing an upper cladding layer on the patterned waveguide material,
wherein the ICP-PECVD process occurs at a temperature less than or equal to 250° C.

2. The method of claim 1, wherein the substrate comprises a substrate material selected from the group consisting of: silicon, quartz, a III-V semiconductor, and a polymer.

3. The method of claim 1, wherein depositing the upper cladding layer comprises flowing vapor precursors of silane, oxygen, and argon onto the lower patterned waveguide material and subjecting the vapor precursors to an ICP-PECVD process which disassociates the silane and oxygen and deposits waveguide material of silicon oxide onto the patterned waveguide material.

4. The method of claim 1, further comprising depositing the lower cladding layer which comprises flowing vapor precursors of deuterated silane, oxygen onto the lower patterned waveguide material and subjecting the vapor precursors to an ICP-PECVD process which disassociates the silane and oxygen and deposits waveguide material of silicon oxide onto the substrate.

5. The method of claim 1, wherein the waveguide material has a thickness of less than 200 nm.

6. The method of claim 5, wherein patterning the waveguide material comprises:
coating the waveguide material with a photoresist;
exposing the photoresist through a mask to transfer a pattern onto the photoresist;
etching the waveguide material through the photoresist; and
removing the photoresist.

7. The method of claim 6, wherein etching the waveguide material is performed with a reactive ion etch process.

8. The method of claim 7, wherein the reactive ion etch process is an inductively coupled plasma-reactive ion etch (ICP-RIE) process, wherein the ICP-RIE process is performed at a temperature of 250° C. or less.

9. The method of claim 1, wherein the waveguide material has a thickness of greater than or equal to 200 nm.

10. The method of claim 9, wherein patterning the waveguide material comprises:
depositing a hard mask layer on the waveguide material;
coating the hard mask layer with a photoresist;
exposing the photoresist through a mask to transfer a pattern onto the photoresist;
etching the hard mask layer through the photoresist;
removing the photoresist;
etching the waveguide material through the hard mask layer; and
removing the hard mask layer.

11. The method of claim 10, wherein etching the waveguide material is performed with a reactive ion etch process.

12. The method of claim 11, wherein the reactive ion etch process is an inductively coupled plasma-reactive ion etch (ICP-RIE) process, wherein the ICP-RIE process is performed at a temperature of 250° C. or less.

13. The method of claim 10, wherein depositing the hard mask layer comprises sputtering a hard mask material onto the waveguide material.

14. The method of claim 10, wherein etching the hard mask layer is performed with a reactive ion etch process.

15. The method of claim 14, wherein the reactive ion etch process is an inductively coupled plasma-reactive ion etch (ICP-RIE) process, wherein the ICP-RIE process is performed at a temperature of 250° C. or less.

16. The method of claim 1, further comprising:
flowing precursors comprising deuterated silane and nitrogen onto the upper cladding layer in the deposition chamber;
subjecting the precursors to an ICP-PECVD process which disassociates the deuterated silane and nitrogen and deposits waveguide material of silicon nitride or silicon oxynitride onto the upper cladding layer; and
patterning the waveguide material into a second patterned waveguide material.

17. A heterogeneously integrated ultra-low loss optical waveguide comprising:
a substrate comprising electronic or photonic circuits in a material system that is not compatible with high temperature processing above 250° C.;
a lower cladding layer positioned on top of the lower substrate fabricated with a maximum temperature of 250° C.;
a first waveguide core layer positioned on top of the lower cladding layer fabricated with a maximum temperature of 250° C.; and
a first upper cladding layer positioned on top of the waveguide core layer fabricated with a maximum temperature of 250° C.

18. The optical waveguide of claim 17, wherein the substrate is selected from the group consisting of: silicon photonics, electronic circuits, printed circuit boards, organic circuits, lithium niobate, barium titanium oxide (BTO), quartz, sapphire, and silicon carbide.

19. The optical waveguide of claim 17, wherein the first waveguide core layer is a nitride layer including a thickness from 20 nm to 1 micron with maximum processing temperature of 250° C.

20. The optical waveguide of claim 17, further comprising a second waveguide core layer positioned on the first upper cladding layer and a second upper cladding layer positioned on the second waveguide core, wherein the second waveguide core and the second upper cladding layer are fabricated with a maximum processing temperature of 250° C.
